(19) United States
(12) Patent Application Publication
(10) Pub. No.: US 2010/0170555 A1
(43) Pub. Date: Jul. 8, 2010

(54) SOLAR CELL, METHOD FOR MANUFACTURING SOLAR CELLS AND ELECTRIC CONDUCTOR TRACK

(76) Inventor: Juan Rechid, Hamburg (DE)

Correspondence Address: FRIEDRICH KUEFFNER, 317 MADISON AVENUE, SUITE 910, NEW YORK, NY, 10017, US

(21) Appl. No.: 12/310,631

(22) PCT Filed: Aug. 15, 2007
(86) PCT No.: PCT/DE2007/001466

§ 371 Date: Dec. 29, 2009

(30) Foreign Application Priority Data
Sep. 1, 2006 (DE) 10 2006 041 046.7

(51) Int. Cl. H01L 31/042; H01L 31/00; H01L 31/18; H01B 5/00

(52) U.S. Cl. 136/244; 136/256; 438/80; 174/126.1; 257/E31.113

(57) ABSTRACT

The solar cell has at least one semiconductor layer arranged on a metal support and is provided with a plurality of contact tracks arranged on the semiconductor layer. A lateral projection by at least one contact track is bent around onto a reverse of the support and arranged so as to be electrically insulated from the support. Adjacently arranged solar cells are preferably inter-connected by conductor tracks which have a perforated form in order to allow local contact-connections by soldering through.

The invention concerns a solar cell that has at least one semiconductor layer arranged on a metallic substrate and is provided with a plurality of contact tracks arranged on the semiconductor layer.

The invention also concerns a method for producing solar cells that have at least one semiconductor layer arranged on a metallic substrate and are provided with a plurality of contact tracks arranged on the semiconductor layer.

Finally, the invention concerns a conductor track for creating an electrical connection.

The aforementioned solar cells can be designed as thin-film solar cells, which are interconnected to form solar modules.

Prior-art solar cells cannot yet meet all of the requirements that are necessary to produce solar modules in different sizes that are compatible with one another. This is a goal that is strived for in order to be able to optimize the utilization of individually available roof surfaces.

Therefore, the objective of the present invention is to design a solar cell of the aforementioned type in such a way that simplified possibilities for interconnecting the solar cells to form solar modules are made available.

In accordance with the invention, the solution to this problem is characterized by the fact that a laterally projecting end of at least one contact track is bent over onto the rear side of the substrate and mounted in such a way that it is electrically insulated from the substrate.

A further objective of the present invention is to improve a method of the aforementioned type in a way that is conducive to high productivity with high reliability.

In accordance with the invention, the solution to this problem is characterized by the fact that at least one contact track, which extends laterally beyond the edge of the substrate, is fixed on the semiconductor layer and then bent over onto the rear side of the substrate and mounted in such a way that it is electrically insulated from the substrate.

Finally, a further objective of the present invention consists in designing a conductor track of the aforementioned type in a way that is conducive to simple processability.

In accordance with the invention, the solution to this problem is characterized by the fact that at least one side of the conductor track is provided with an insulating layer and that both the conductor track and the insulating layer are provided with a plurality of perforations.

The solar cell design of the invention, the use of the method for producing the solar cell, and the constructive realization of the conductor track assist to a considerable extent with the interconnection of individual solar cells to form solar modules. In particular, it is possible, with an outer appearance that is essentially the same, to produce modules with different electrical parameters. The individual solar cells can be interconnected in any desired way without there being any appreciable change in the appearance of the complete solar module.

In particular, the solar cells designed in accordance with the invention are fully compatible with a shingle-like interconnection of solar cells in accordance with the prior art. However, the shingle-like interconnection with the use of the solar cells of the invention can be carried out much more effectively than with the prior art.

The solar modules produced from the solar cells of the invention are compatible with one another and can be fabricated in different sizes. The solar modules also match one another visually in different constructive realizations and have a uniform design. Within the solar modules, the individual solar cells can be uniformly oriented. The module current or module voltage can be identically predetermined in all module sizes, so that the modules can optionally be interconnected in series or in parallel.

It is conducive to continuous production for the substrate to be formed as a metal strip.

To reduce consumption of material when the necessary contacting is taking place, it is useful for the contact tracks to be arranged transversely to the longitudinal direction of the substrate.

In particular, it is proposed that the contact tracks project laterally beyond the strip of substrate and can thus be used for the interconnection.

To facilitate continuous production, it is proposed that the contact tracks extend in the longitudinal direction of the substrate.

In a production method of this type, it has been found to be effective for collector tracks to be arranged transversely to the longitudinal direction and transversely to the contact tracks and to be electrically connected with the contact tracks.

Typically, it is contemplated that the rear side of the substrate is designed as an opposite contact.

To facilitate the fixing of the bent-over contact tracks or collector tracks on the rear side of the substrate, it is proposed that the contact tracks or collector tracks be adhesively bonded to the rear side of the substrate.

In a typical design, at least one of the contact tracks or collector tracks is formed as copper wire.

It is also possible for at least one of the contact tracks or collector tracks to be formed as copper strip.

The assembly of solar modules from individual solar cells is assisted if a plurality of solar cells is interconnected in such a way that a contact track or collector track bent over onto the rear side of the substrate is electrically connected with the rear side of an adjacent substrate.

Similarly, adjacent solar cells can be connected in a simple way by electrically connecting them by at least one conductor track.

In an advantageous design, the semiconductor layers are formed as CIS/TCO layers.

For industrial production, it has been found to be effective for the semiconductor layers to be arranged on a strip-shaped substrate.

The production rate can be increased by unwinding the contact tracks from a supply roll in the longitudinal direction of the substrate.

Simplified contacting is provided if the contact tracks running in the longitudinal direction are electrically connected with collector tracks running transversely to the longitudinal direction.

Production can be simplified by adhesively bonding the contact tracks or collector tracks after they have been bent over onto the rear side of the substrate.

To supply a sufficiently large output voltage of solar modules, it is proposed that at least two solar cells be connected in series.

A large available output voltage can be generated by connecting at least two solar cells in parallel.

Production can be significantly simplified by connecting at least two solar cells with each other by a conductor track that has perforations through which a soldered connection is produced.

With respect to simplified production, it is also helpful if the insulating layer is provided with a layer of adhesive in the area of its surface that faces away from a metallic layer.

In a typical embodiment, the metallic layer consists of copper.

The drawings show schematic representations of specific embodiments of the invention.

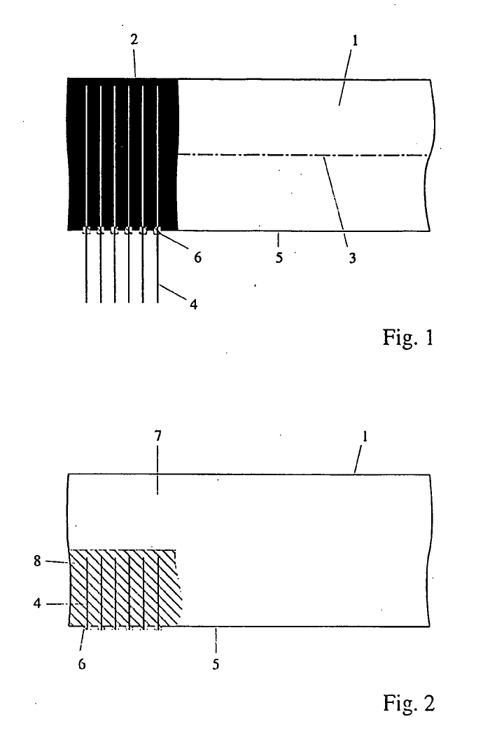

FIG. 1 is a schematic drawing of a strip-shaped substrate with solar cell and laterally projecting contact tracks.

FIG. 2 is a drawing of the device shown in FIG. 1 but viewed from the rear after the projecting contact tracks have been bent over.

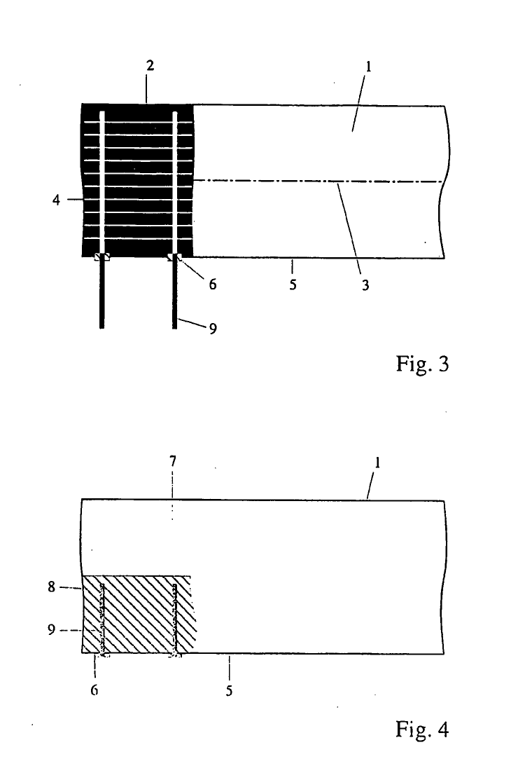

FIG. 3 shows an embodiment that is modified from the embodiment of FIG. 1, in which the contact tracks extend in the longitudinal direction of the strip and are interconnected with collector tracks that run transversely to the longitudinal direction.

FIG. 4 shows the device of FIG. 3 but viewed from the rear after the collector tracks have been folded over onto the rear side.

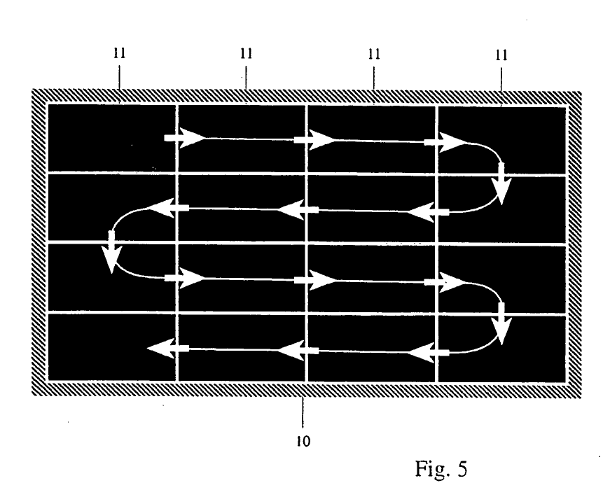

FIG. 5 is a graphic representation of the current flow in a solar module formed from individual solar cells.

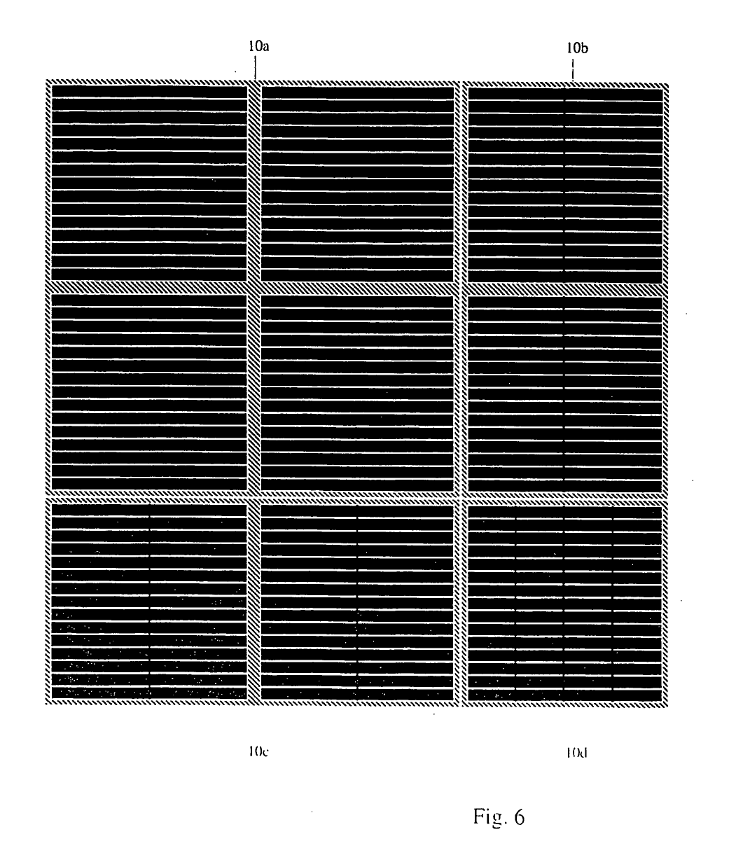

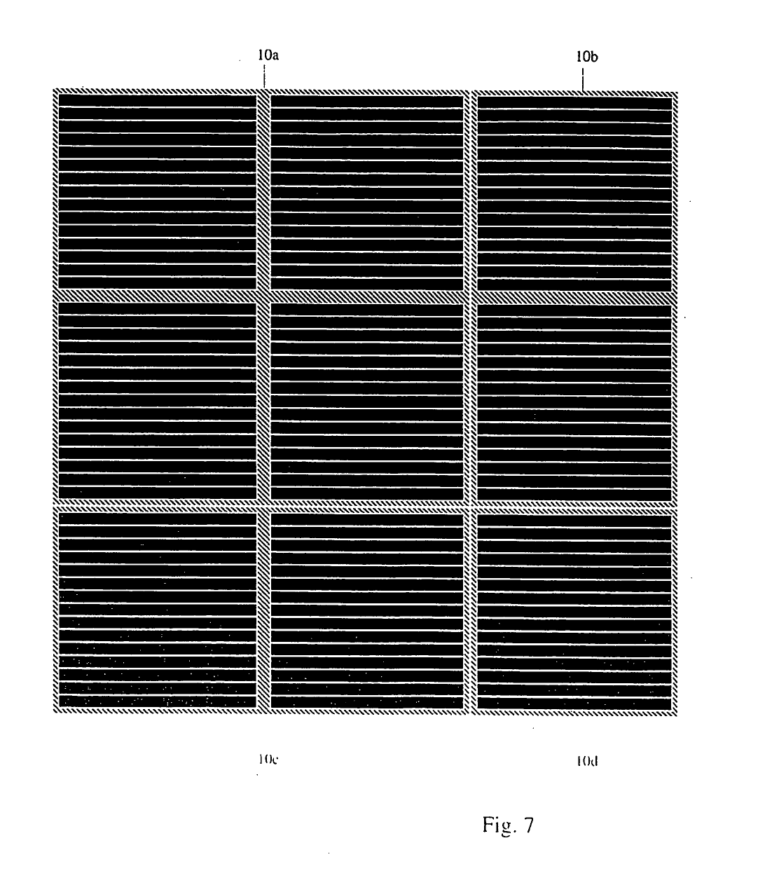

FIG. 6 shows an arrangement of several solar modules for supplying the same output voltage.

FIG. 7 shows an arrangement of solar modules for supplying the same output current.

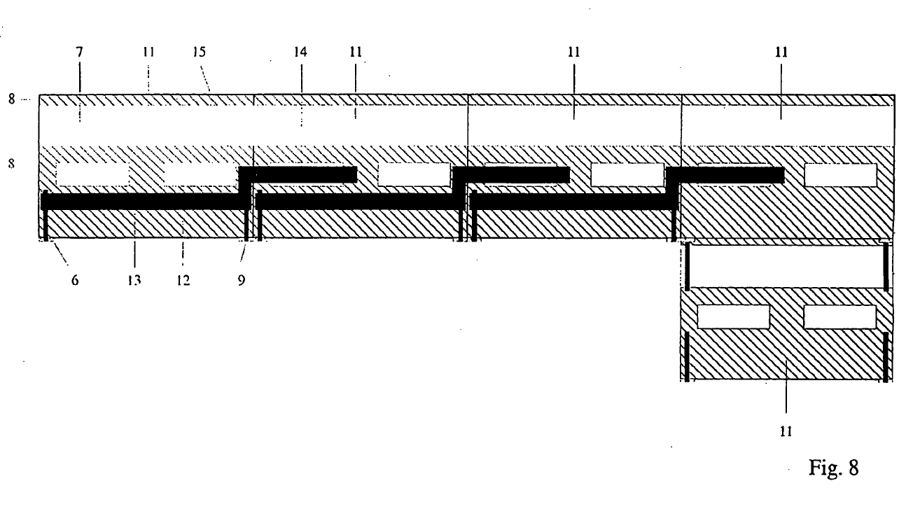

FIG. 8 is a schematic drawing that illustrates the electrical connection of a plurality of individual solar cells.

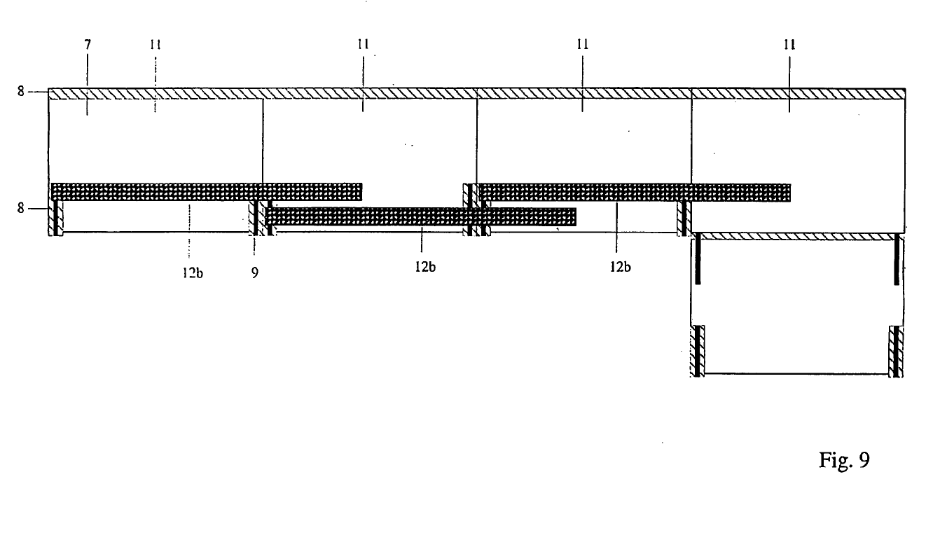

FIG. 9 shows an embodiment that is modified from the embodiment of FIG. 8, in which perforated conductor tracks are used.

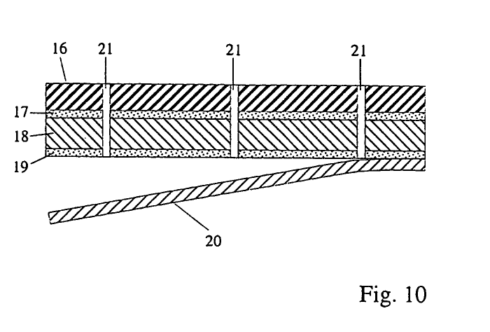

FIG. 10 shows the layered structure of the perforated conductor tracks.

In the embodiment illustrated in FIG. 1, semiconductor layers 2 are arranged on a metallic substrate 1, which is formed as a strip and is made, for example, of special steel. The semiconductor layers 2 are designed to convert incident light to electric energy. A plurality of contact tracks 4 is arranged transversely to the longitudinal direction 3 of the substrate. The contact tracks 4 extend laterally over one edge 5 of the substrate 1.

To produce individual solar cells, suitably long sections of the substrate 1 with the semiconductor layers 2 and the contact tracks 4 are cut off.

To avoid electrical connection of the contact track 4 with the metallic substrate 1, insulators 6 are mounted along the edge 5. The insulators 6 are preferably realized as edge insulators.

In the rear view in FIG. 2, the contact tracks 4 that project over the edge, as illustrated in FIG. 1, are bent over and fixed on the rear side 7 of the substrate 1.

This is preferably accomplished by adhesive bonding. In the area of the rear side 7, the contact tracks 4 that have been bent over are arranged on an insulator 8, so that here too electrical contact with the metallic substrate 1 is avoided.

In the embodiment illustrated in FIG. 3, the contact tracks 4 are oriented in the longitudinal direction 3 of the substrate 1. To allow a plurality of individual solar cells to be interconnected, collector tracks 9 extend transversely to the longitudinal direction and extend laterally beyond the edge 5. The handling of these laterally projecting collector tracks 9 is essentially identical to the handling of the laterally projecting contact tracks 4 according to FIGS. 1 and 2, which was explained above. The embodiment shown in FIG. 3 has the advantages that when the solar cells are produced on an industrial scale, the contact tracks 4 can be more easily arranged in the longitudinal direction 3 and that the number of collector tracks 9 projecting laterally beyond the edge 5 of the substrate 1 is smaller than the number of contact tracks 4 projecting over the edge 5 in the embodiment according to FIG. 1. The contact tracks 4 essentially serve the function of contacting the semiconductor layer.

FIG. 4 shows, in analogy to FIG. 2, the constructive realization after the laterally projecting contact tracks 9 have been bent over onto the rear side 7 of the substrate 1. An insulator 8 is also used here.

To produce a solar module from individual solar cells, a plurality of small solar cells can be connected with one another in series. This provides the size of the desired solar module. In this regard, the individual solar cells are interconnected in such a way that the rear-side front contacts with an electric conductor are connected with the rear side of the adjacent cell. This makes it possible to produce individual assemblies of cells, which consist of several individual solar cells and have the visual appearance of a single large cell. The individual multicell shingles in turn are interconnected with standard shingle technology.

FIG. 5 shows a solar module of this type 10, which is constructed from a plurality of individual solar cells 11. The arrows illustrate how the current flows in meandering fashion through the solar cells 11.

The solar cells 11 and the solar modules 10 can be flexibly constructed, especially if thin substrates 1 are used, so that mounting on a large number of differently constructed foundations is possible.

FIG. 6 shows several solar modules 10, in which the solar cells 11 are arranged in such a way that all of the solar modules 10 supply the same voltage. In the embodiment shown in FIG. 7, the solar cells 11 are arranged in such a way that all of the solar modules 10 supply the same output current.

With the same outer appearance, the smaller solar modules 10b to 10d can thus be optionally designed with the same voltage or the same current as the large solar module 10a.

The contact tracks 4 and/or the collector tracks 9 can be realized as copper wires or copper strips. Especially so-called CIS/TCO layers can be considered for use as the semiconductor layer. The contact tracks can be applied with the use of conductive adhesives, soldering or laser welding.

FIG. 8 illustrates the electrical connection of a plurality of individual solar cells 11. The solar cells 11 are connected in series here. Conductor tracks 12 are used to connect the contact tracks 4 or collector tracks 9 of a solar cell 11, which are bent over onto the rear side 7, with the metallic substrate 1 of an adjacent cell. In this embodiment, each conductor track 12 consists of two longitudinal segments 13, 14 and a transverse segment 15 that connects the longitudinal segments 13, 14 with each other.

FIG. 9 shows an embodiment that is modified from the embodiment of FIG. 8, in which perforated conductor tracks 12b are used. The conductor tracks 12b have the cross-sectional structure illustrated in FIG. 10. A metallic layer 16 is joined by an adhesive 17 with an insulating layer 18, which in turn is provided with a layer of adhesive 19 on its surface that faces away from the metallic layer 16. Before use, the adhesive layer 19 is provided with a peelable covering 20. The connecting track 12 is provided with a large number of perforations 21.

The conductor tracks 12b are used in such a way that after the cover 20 is peeled off, the cells are adhesively attached to any desired foundation, including especially a conductive foundation. The metallic layer 16 is insulated from a conductive foundation by the insulating layer 18. Soldering is carried out through the perforations 21 in the area of electrical contacting that is to be made. The metallic layer 16 contacts an electrically conductive substrate 1 or the contact tracks 4 or the collector tracks 9 exclusively in these soldered areas.

Due to the suitable structure of the conductor tracks 12b, the conductor tracks 12b according to FIG. 9 can be processed in the form of strips and thus in a straight line. Compared to the processing in FIG. 8, this makes it possible to realize considerable savings in production costs.

1. A solar cell that has at least one semiconductor layer arranged on a metallic substrate and is provided with a plurality of collector tracks arranged on the semiconductor layer, wherein a laterally projecting end of at least one contact track (4) or one collector track (9) is bent over onto the rear side (7) of the substrate (1) and mounted in such a way that it is electrically insulated from the substrate (1).

2. A solar cell in accordance with claim 1, wherein the substrate (1) is formed as a metal strip.

3. A solar cell in accordance with claim 1, wherein the contact tracks (4) are arranged transversely to the longitudinal direction (3) of the substrate (1).

4. A solar cell in accordance with claim 3, wherein the contact tracks (4) project laterally beyond one edge (5) of the substrate (1).

5. A solar cell in accordance with claim 1, wherein the collector tracks (9) extend in the longitudinal direction (3) of the substrate (1).

6. A solar cell in accordance with claim 5, wherein the collector tracks (9) are arranged transversely to the longitudinal direction (3) and transversely to the contact tracks (4) and are electrically connected with the contact tracks (4).

7. A solar cell in accordance with claim 6, wherein the collector tracks (9) project laterally beyond one edge (5) of the substrate (1).

8. A solar cell in accordance with claim 1, wherein the rear side (7) of the substrate (1) is designed as an opposite contact.

9. A solar cell in accordance with claim 1, wherein the contact tracks (4) or collector tracks (9) are adhesively bonded to the rear side (7) of the substrate (1).

10. A solar cell in accordance with claim 1, wherein at least one of the contact tracks (4) or collector tracks (9) is formed as copper wire.

11. A solar cell in accordance with claim 1, wherein at least one of the contact tracks (4) or collector tracks (9) is formed as copper strip.

12. A solar cell in accordance with claim 1, wherein a plurality of solar cells (11) is interconnected in such a way that at least one contact track (4) or collector track (9) bent over onto the rear side (7) of the substrate (1) is electrically connected with the rear side (7) of an adjacent substrate (1).

13. A solar cell in accordance with claim 1, wherein adjacent solar cells (11) are electrically connected with each other by at least one conductor track (12).

14. A solar cell in accordance with claim 1, wherein the semiconductor layers are formed as CIS/TCO layers.

15. A solar cell in accordance with claim 1, wherein the contact tracks (4) are applied with the use of a conductive adhesive, solder, or laser welding.

16. A method for producing solar cells that have at least one semiconductor layer arranged on a metallic substrate and are provided with a plurality of contact tracks arranged on the semiconductor layer, wherein at least one contact track (4) or collector track (9), which extends laterally beyond the edge (5) of the substrate (1), is fixed on the semiconductor layer (2) and then bent over onto the rear side (7) of the substrate (1) and mounted in such a way that it is electrically insulated from the substrate (1).

17. A method in accordance with claim 16, wherein the semiconductor layer (2) is arranged on a strip-shaped substrate (1).

18. A method in accordance with claim 16, wherein the contact tracks (4) are unwound from a supply roll in the longitudinal direction (3) of the substrate (1).

19. A method in accordance with claim 16, wherein the contact tracks (4) running in the longitudinal direction (3) are electrically connected with collector tracks (9) running transversely to the longitudinal direction (3).

20. A method in accordance with claim 16, wherein the collector tracks (9) are adhesively bonded after they have been bent over onto the rear side (7) of the substrate (1).

21. A method in accordance with claim 16, wherein at least two solar cells (11) are connected in series.

22. A method in accordance with claim 16, wherein at least two solar cells (11) are connected in parallel.

23. A method in accordance with claim 16, wherein at least two solar cells (11) are connected with each other by a conductor track (12b) that has perforations through which a soldered connection is produced.

24. A conductor track for producing an electrical connection, wherein at least one side of the conductor track is provided with an insulating layer (18), where both the conductor track and the insulating layer (18) are provided with a plurality of perforations (21).

25. A conductor track in accordance with claim 24, wherein the insulating layer (18) is provided with a layer of adhesive (19) in the area of its surface that faces away from a metallic layer (16).

26. A conductor track in accordance with claim 24, wherein the metallic layer (16) consists of copper.
